(19) United States
(12) Patent Application Publication
(10) Pub. No.: US 2024/0291486 A1
(43) Pub. Date: Aug. 29, 2024

(54) DRIVING CAPABILITY CONTROL DEVICE AND DRIVING CAPABILITY CONTROL SYSTEM

(71) Applicant: LAPIS Technology Co., Ltd., Yokohama (JP)

(72) Inventor: Mitsuru ARAI, Yokohama (JP)

(73) Assignee: LAPIS Technology Co., Ltd., Yokohama (JP)

(21) Appl. No.: 18/581,313

(22) Filed: Feb. 19, 2024

(30) Foreign Application Priority Data
Feb. 28, 2023 (JP) 2023-030375

(51) Int. Cl. H03K 17/687

(52) U.S. Cl. CPC H03K 17/6872

(57) ABSTRACT

A driving capability control device includes: an averaging circuit, averaging and outputting a drive signal including a pulse train supplied by a driver; a comparison circuit, outputting a comparison result of an output voltage level of the averaging circuit and a predetermined threshold voltage level; and a control circuit, outputting a control signal for controlling a driving capability of the drive signal based on an output of the comparison circuit.

### CROSS-REFERENCE TO RELATED APPLICATION

This application claims priority under 35 USC 119 from Japanese Patent application No. 2023-030375 filed on Feb. 28, 2023, the disclosure of which is incorporated by reference herein.

### BACKGROUND

### Technical Field

The disclosure relates to a driving capability control device and a driving capability control system.

### Description of Related Art

The following technology is known as a technology related to controlling the driving capability of the output signal of a driver. Patent Document 1 (International Publication No. 2009/139057) describes a method for adjusting the output current of a driver that supplies output current to an external load according to an input signal. The driver includes multiple stages of PMOS and multiple stages of NMOS, receives a signal according to the value of the current output from the driver, and adjusts the number of PMOS driving stages or NMOS driving stages according to the level of the signal so that the level of the signal falls within a predetermined range.

Patent Document 2 (Japanese Patent Application Laid-Open (JP-A) No. 2022-92887) describes a driver, which includes an output stage, a slew rate detection portion, and an adjustment portion. The output stage is configured to drive the switch element with a driving capability corresponding to the setting signal; the slew rate detection portion is configured to generate a detection signal according to a slew rate of an output voltage appearing at one end of the switch element; and the adjustment portion is configured to adjust a setting signal read from a non-volatile memory according to the detection signal and output the setting signal to the output stage.

Patent Document 3 (Japanese Patent Application Laid-Open (JP-A) No. 2007-209030) describes a driver circuit having a driver control method and a driver method. The driver control method compares the data of the input signal of the driver with the data of one cycle ago and outputs a driver control signal when they are different, and the driver method increases the driving capability by the driver control signal.

The driver used for the high-speed interface outputs a drive signal with a frequency on the order of gigahertz. The driving capability of the drive signal output from the driver varies depending on the operating environment such as operating speed (frequency) and external load.

When the driving capability of the drive signal is insufficient, the signal level is in a low state and may not be able to exceed the threshold level in binary determination. Although it is desirable to adjust the driving capability of the drive signal according to the operating environment, it is not easy to manually adjust the driving capability.

The disclosure has been made in view of the above points, and aims to automate the adjustment of the driving capability of the drive signal output from the driver.

### SUMMARY

A driving capability control device of the disclosure includes an averaging circuit, averaging and outputting a drive signal including a pulse train supplied by a driver; a comparison circuit, outputting a comparison result of an output voltage level of the averaging circuit and a predetermined threshold voltage level; and a control circuit, outputting a control signal for controlling a driving capability of the drive signal based on an output of the comparison circuit.

A driving capability control system according to the disclosure includes the above-mentioned driving capability control device and the driver. The driver adjusts the driving capability of the drive signal based on the control signal.

### BRIEF DESCRIPTION OF THE DRAWINGS

FIG. 1 is a diagram illustrating an example of the configuration of the driving capability control system according to the embodiment of the disclosure.

FIG. 2 is a diagram illustrating an example of the detailed configuration of the drive circuit according to the embodiment of the disclosure.

FIG. 3A is a diagram illustrating an example of the input/output voltage of the averaging circuit when the driving capability of the drive signal is relatively low.

FIG. 3B is a diagram illustrating an example of the input/output voltage of the averaging circuit when the driving capability of the drive signal is relatively high.

FIG. 4 is a flowchart illustrating an example of the processing flow performed by the control circuit according to the embodiment of the disclosure.

FIG. 5 is a time chart illustrating an example of the operation of the driving capability control system according to the embodiment of the disclosure.

### DESCRIPTION OF THE EMBODIMENTS

An example of the embodiment of the disclosure is described below with reference to the drawings. In addition, same or equivalent components and parts are given the same reference signs in each drawing, and redundant descriptions are omitted.

By using the technology of the disclosure, the adjustment of the driving capability of the drive signal output from the driver may be automated.

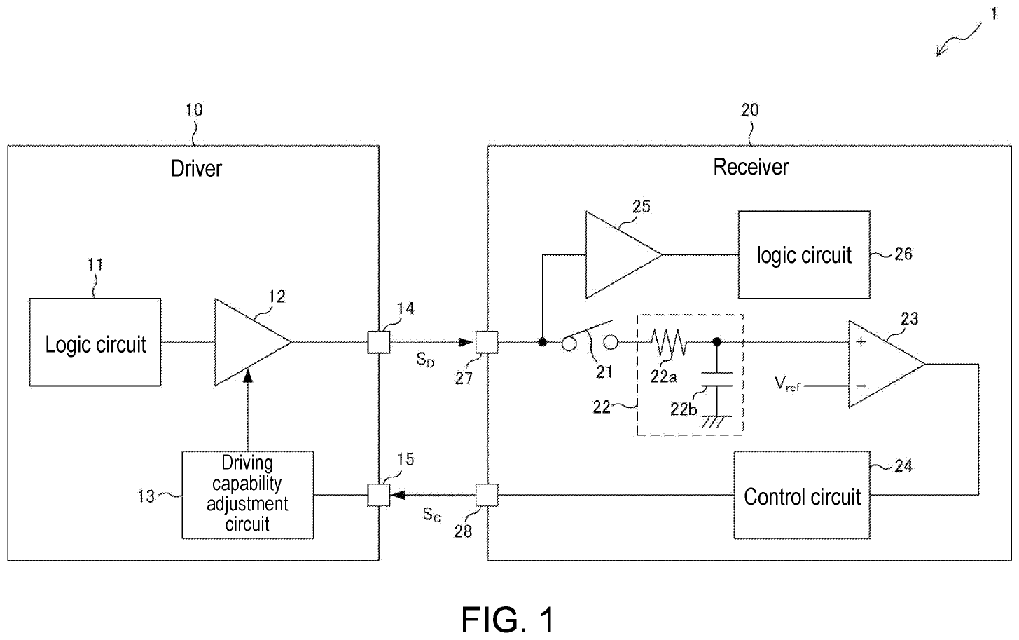

FIG. 1 is a diagram illustrating an example of the configuration of the driving capability control system 1 according to the embodiment of the disclosure. The driving capability control system 1 includes a driver 10 and a receiver 20. In the driving capability control system 1, the receiver 20 receives a drive signal S_{D} output from the driver 10 and has both the function of processing the received drive signal S_{D} and controlling the driving capability of the drive signal SD. The receiver 20 is an example of the “driving capability control device” in the disclosure. The driver 10 includes a logic circuit 11, a drive circuit 12, and a driving capability

adjustment circuit 13. The driver 10 operates in any of the operating modes: adjustment mode and normal mode. The adjustment mode is an operation mode for adjusting the driving capability of the drive signal S_{D} output from the drive circuit 12. The normal mode is an operation mode under normal conditions. The driver 10 switches the operating mode based on a control signal S_{C} supplied by the receiver 20.

The logic circuit 11 is enabled in normal mode, generates the drive signal S_{D} to be supplied to the receiver 20, and supplies the same to the drive circuit 12. On the other hand, the logic circuit 11 is disabled in adjustment mode and stops supplying the drive signal S_{D} to the drive circuit 12.

The driving capability adjustment circuit 13 performs the control for adjusting the driving capability of the drive signal S_{D} output from the drive circuit 12 based on the control signal S_{C} supplied by the receiver 20. In the adjustment mode, the driving capability adjustment circuit 13 generates the drive signal S_{D} for adjusting the driving capability and supplies the same to the drive circuit 12. The drive signal S_{D} for adjusting the driving capability is a pulse signal that includes a pulse train with a constant duty and period. Further, the driving capability adjustment circuit 13 supplies an adjustment value of the driving capability of the drive signal S_{D} output from the drive circuit 12 to the drive circuit 12 based on the control signal S_{C} supplied by the receiver 20. The control signal S_{C} from the receiver 20 is supplied to the driving capability adjustment circuit 13 via an input terminal 15.

In the drive circuit 12, under the normal operating mode, power amplification is performed on the drive signal S_{D} supplied by the logic circuit 11 and output; and under the adjustment mode, power amplification is performed on the drive signal S_{D} for adjusting the driving capability supplied by the driving capability adjustment circuit 13 and output.

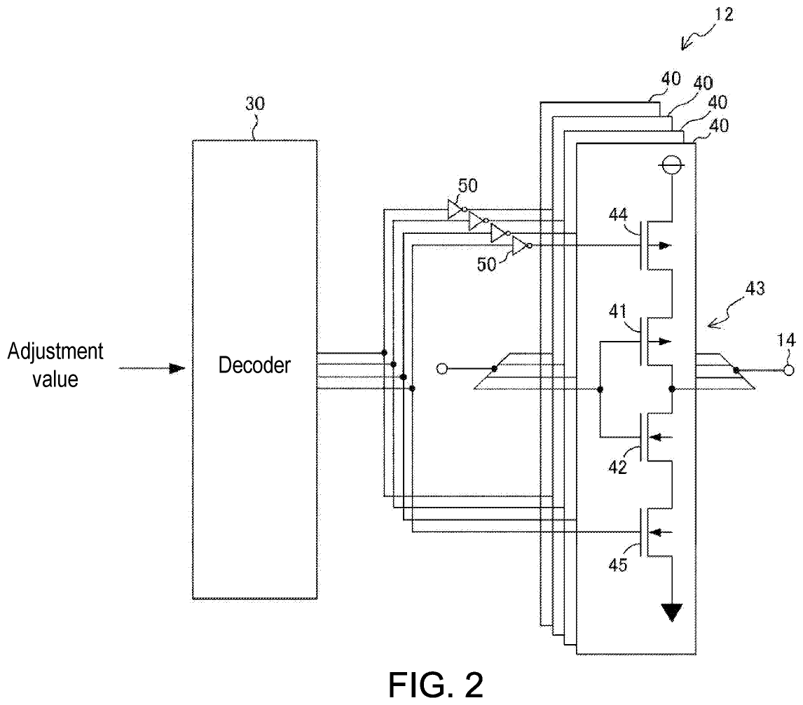

FIG. 2 is a diagram illustrating an example of the detailed configuration of the drive circuit 12. The drive circuit 12 includes a decoder 30 and multiple output circuits 40. Each of the output circuits 40 includes a CMOS circuit 43 having a P-channel type transistor 41 and an N-channel type transistor 42. In the output circuits 40, the inputs and outputs of the CMOS circuits 43 are connected to each other. That is, the CMOS circuits 43 are connected in series. For the input of the CMOS circuit 43, under the normal operating mode, the drive signal S_{D} from the logic circuit 11 is input; and under the adjustment mode, the drive signal S_{D} for adjusting the driving capability from the driving capability adjustment circuit 13 is input. The drive signal S_{D} that is power amplified is output from the output of the CMOS circuit 43. The output of the CMOS circuit 43 is connected to an output terminal 14, and the power amplified drive signal S_{D} is supplied to the receiver 20 via the output terminal 14.

Each of the output circuits 40 has a P-channel type transistor 44 and an N-channel type transistor 45 controlled by the decoder 30. The transistor 44 has the source connected to the power supply line and the drain connected to the sources of the transistor 41. The transistor 45 has the drain connected to the source of the transistor 42 and the source connected to the ground line. The gate of the transistor 44 is connected to the gate of the transistor 45 via an inverter 50, and the connection nodes therebetween are connected to the decoder 30. The decode signal output from the decoder 30 is input to the gate of the transistor 45 and is also input to the gate of the transistor 44 via the inverter 50. The transistors 44 and 45 are turned on and off integrally according to the decode signal supplied by the decoder 30. In each of the output circuits 40, when the transistors 44 and 45 are turned on, the output circuit 40 is enabled. The output circuits 40 are selectively enabled according to the decode signal supplied by the decoder 30. The greater the number of output circuits 40 that are enabled, the higher the driving capability of the drive signal S_{D} output from the drive circuit 12.

The decoder 30 generates the decode signal based on the adjustment value supplied by the driving capability adjustment circuit 13. That is, the number of output circuits 40 to be enabled is determined by the adjustment value supplied by the driving capability adjustment circuit 13.

The receiver 20 includes a switch 21, an averaging circuit 22, a comparison circuit 23, a control circuit 24, a receiving circuit 25, and a logic circuit 26. The switch 21 has one end connected to an input terminal 27 into which the drive signal S_{D} from the driver 10 is input, and the other end connected to the averaging circuit 22. The switch 21 switches between supplying and non-supplying the drive signal S_{D} to the averaging circuit 22 according to the instruction from the control circuit 24. When the switch 21 is turned on, the drive signal S_{D} is supplied to the averaging circuit 22; and when the switch 21 is turned off, the supply of the drive signal S_{D} to the averaging circuit 22 is cut off. The switch 21 is turned on in adjustment mode and turned off in normal mode. That is, the averaging circuit 22 is supplied with the drive signal S_{D} for adjusting the driving capability in the adjustment mode.

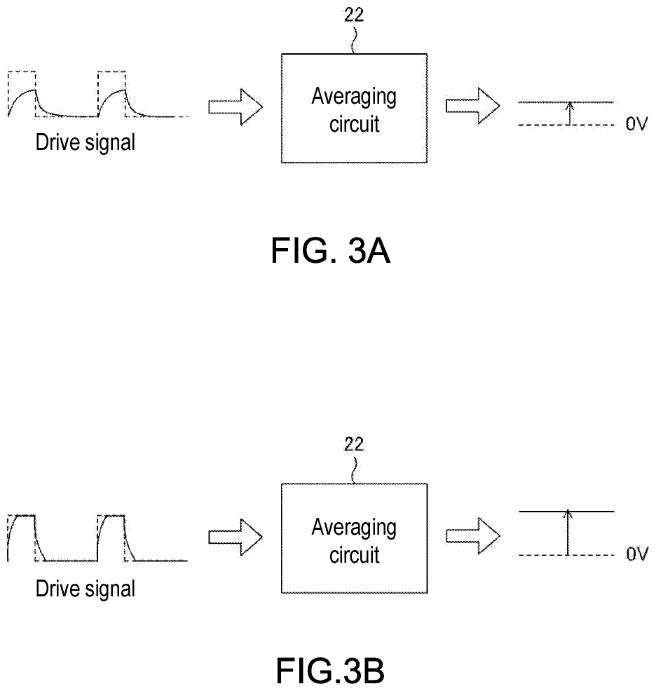

The averaging circuit 22 averages and outputs the drive signal S_{D} for adjusting the driving capability, including the pulse train. That is, the averaging circuit 22 outputs a voltage at a constant level according to the height of the pulse included in the drive signal S_{D} for adjusting the driving capability and the duty of the drive signal Sp. FIG. 3A is a diagram illustrating an example of the input/output voltage of the averaging circuit 22 when the driving capability of the drive signal S_{D} is relatively low. FIG. 3B is a diagram illustrating an example of the input/output voltage of the averaging circuit 22 when the driving capability of the drive signal S_{D} is relatively high. The higher the driving capability of the drive signal S_{D}, the steeper the rise of the pulse included in the drive signal S_{D}, and since the height of the pulse becomes high, the output voltage level of the averaging circuit 22 becomes high. In this embodiment, the averaging circuit 22 is configured by a low pass filter including a resistance element 22a and a capacitor 22b.

The comparison circuit 23 is a comparator that outputs a comparison result of an output voltage level of the averaging circuit 22 and a predetermined threshold voltage V_{ref} level. The comparison circuit 23 in this embodiment outputs a high-level output signal when the output voltage level of the averaging circuit 22 is higher than the predetermined threshold voltage V_{ref} level and a low-level output signal otherwise. The comparison circuit 23 is enabled according to the instruction from the control circuit 24. The comparison circuit 23 is enabled in adjustment mode and disabled in normal mode.

The receiving circuit 25 has an input end connected to the input terminal 27 and an output

end connected to the logic circuit 26. The receiving circuit 25 performs waveform shaping on the drive signal S_{D} supplied by the driver 10. The logic circuit 26 processes the drive signal SD whose waveform has been shaped by the receiving circuit 25. The logic circuit 26 is an example of the “processing circuit” in the disclosure. The receiving circuit 25 and the logic circuit 26 are enabled according to the instruction from the control circuit 24. The receiving circuit 25 and the logic circuit 26 are enabled in normal mode and disabled in adjustment mode.

The control circuit 24 controls the switch 21, the averaging circuit 22, the comparison circuit 23, the receiving circuit 25, and the logic circuit 26. Further, the control circuit 24 controls the driving capability of the drive signal S_{D} output from the driver 10. The control circuit 24 sets the operating mode of the driver 10 and the receiver 20 to adjustment mode when the driving capability control system 1 is started. The control circuit 24 controls the switch 21 to be turned on in the adjustment mode, thereby supplying the drive signal S_{D} for adjusting the driving capability to the averaging circuit 22. Further, in the adjustment mode, the control circuit 24 enables the comparison circuit 23 and disables the receiving circuit 25 and the logic circuit 26.

The control circuit 24 outputs a first control signal including the instruction to start adjusting the driving capability of the drive signal S_{D} when the driving capability control system 1 is started. The control circuit 24 outputs a second control signal, which includes an instruction to continue adjusting the driving capability of the drive signal S_{D}, when an output indicating that the output voltage level of the averaging circuit 22 is lower than the threshold voltage V_{ref} level (i.e., a low level signal) is output from the comparison circuit 23. The control circuit 24 outputs a third control signal, which includes an instruction to stop adjusting the driving capability of the drive signal S_{D}, when an output indicating that the output voltage level of the averaging circuit 22 is higher than the threshold voltage V_{ref} level (i.e., a high level signal) is output from the comparison circuit 23. The first to third control signals are output from the output terminal 28 and input to the input terminal 15 of the driver 10.

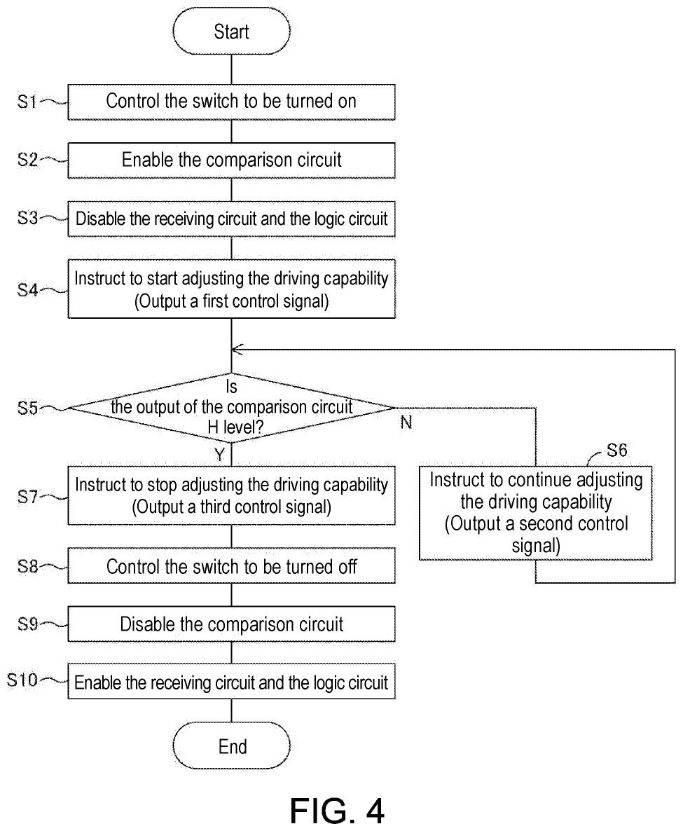

FIG. 4 is a flowchart illustrating an example of the processing flow performed by the control circuit 24. When the driving capability control system 1 is started, the control circuit 24 starts processing.

In step S1, the control circuit 24 controls the switch 21 to be turned on. In step S2, the control circuit 24 enables the comparison circuit 23. In step S3, the control circuit 24 disables the receiving circuit 25 and the logic circuit. In step S4, the control circuit 24 supplies the driver 10 with the first control signal including an instruction to start adjusting the driving capability of the drive signal Sp. Through the processing from steps S1 to S4, the transition of the operating mode of the driver 10 and the receiver 20 to the adjustment mode is completed.

When the driving capability adjustment circuit 13 of the driver 10 receives the first control signal from the receiver 20, the drive signal S_{D} for adjusting the driving capability and the adjustment value of the driving capability are supplied to the drive circuit 12. In the drive circuit 12, the number of output circuits 40 determined by the adjustment value supplied by the driving capability adjustment circuit 13 are enabled. The drive signal S_{D} for adjusting the driving capability is power amplified by the enabled output circuit 40 and supplied to the receiver 20. The driving capability of the drive signal S_{D} becomes higher as the number of enabled output circuits 40 increases. The drive signal S_{D} for adjusting the driving capability is averaged by the averaging circuit 22. The comparison circuit 23 outputs a comparison result of an output voltage level of the averaging circuit 22 and a predetermined threshold voltage V_{ref} level.

In step S5, the control circuit 24 determines whether the comparison circuit 23 outputs an output indicating that the output voltage level of the averaging circuit 22 is higher than the threshold voltage V_{ref} level. That is, in this embodiment, the control circuit 24 determines whether the output of the comparison circuit 23 is the high level. In the case of the output indicating that the output voltage level of the averaging circuit 22 is higher than the threshold voltage V_{ref} level (i.e., a high level signal) is not output from the comparison circuit 23, the process moves to step S6. On the other hand, in the case of the output indicating that the output voltage level of the averaging circuit 22 is higher than the threshold voltage V_{ref} level (i.e., a high level signal) is output from the comparison circuit 23, the process moves to step S7.

In step S6, the control circuit 24 supplies the driver 10 with the second control signal including the instruction to continue adjusting the driving capability of the drive signal Sp. After that, the process returns to step S5.

When the driving capability adjustment circuit 13 of the driver 10 receives the second control signal from the receiver 20, the supply of the drive signal S_{D} for adjusting the driving capability to the drive circuit 12 is maintained, and a greater adjustment value compared to the previous time is supplied to the drive circuit 12. In this way, the number of output circuits 40 enabled in the drive circuit 12 increases compared to the previous time. As a result, the driving capability of the drive signal S_{D} becomes higher than the previous time, and the output voltage level of the averaging circuit 22 becomes higher than the previous time.

The control circuit 24 continuously supplies the second control signal to the driver 10 every predetermined period until the output of the comparison circuit 23 becomes the high level. The driving capability adjustment circuit 13 stepwise increases the adjustment value according to the second control signal supplied every predetermined period to stepwise increase the driving capability of the drive signal Sp. The high level signal output from the comparison circuit 23 means that the driving capability of the drive signal S_{D} satisfies the required level.

In step S7, the control circuit 24 supplies the driver 10 with the third control signal including the instruction to stop adjusting the driving capability. In step S8, the control circuit 24 controls the switch 21 to be turned off. In step S9, the control circuit 24 disable the comparison circuit 23. In step S10, the control circuit 24 enables the receiving circuit 25 and the logic circuit 26. Through the processing from steps S7 to S10, the transition of the operating mode of the driver 10 and the receiver 20 to the normal mode is completed.

The driver 10 transits the operating mode to the normal mode according to the third control signal, and the logic circuit 11 is enabled. The driver 10 perform power amplification on the drive signal S_{D} generated by the logic circuit 11 using the drive circuit 12 whose driving capability is adjusted, and supplies the same to the receiver 20. In normal mode, the drive signal S_{D} supplied to the receiver 20 is processed in the receiving circuit 25 and the logic circuit 26.

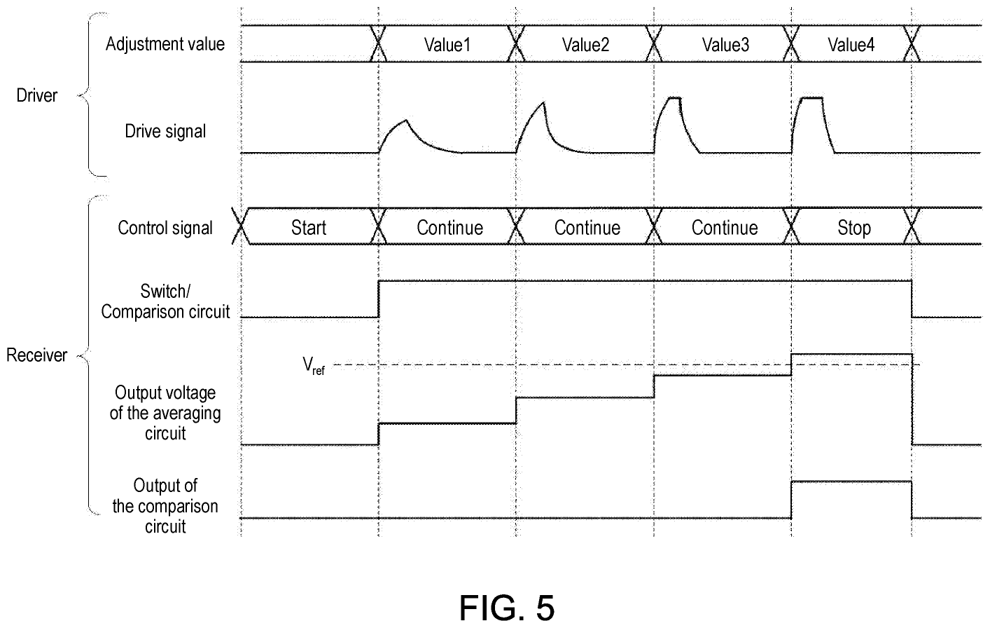

FIG. 5 is a time chart illustrating an example of the operation of the driving capability control system 1. FIG. 5 illustrates, from top to bottom, the adjustment value of the driving capability, the states of the drive signal SD, the control signal S_{C}, the switch 21, and the comparison circuit 23, and the output voltage of the averaging circuit 22 and the output of the comparison circuit 23. The states of the switch 21 and the comparison circuit 23 are as follows: a high level corresponds to the switch 21 being turned on and the comparison circuit 23 being enabled, and a low level corresponds to the switch 21 being turned off and the comparison circuit 23 being disabled. Further, in order to avoid the complexity of the drawing, FIG. 5 shows the drive signal S_{D} in which the number of pulses included in one UI (unit interval) is only one, and in one UI, the number of pulses included in the drive signal S_{D} may be two or more. In FIG. 5, the adjustment value is stepwise increased from “1” to “4” until the output voltage level of the averaging circuit 22 exceeds the threshold voltage V_{ref}, which shows that the driving capability of the drive signal S_{D} is stepwise increased.

As described above, the receiver 20 according to the embodiment of the disclosure functions as a driving capability control device that controls the driving capability of the drive signal S_{D} supplied by the driver 10. The receiver 20 includes: the averaging circuit 22 that averages and outputs the drive signal S_{D} including the pulse train supplied by the driver 10; the comparison circuit 23 that outputs the comparison result of the output voltage level of the averaging circuit 22 and the predetermined threshold voltage V_{ref} level; and the control circuit 24 that outputs the control signal S_{C} for controlling the driving capability of the drive signal S_{D} based on the output of the comparison circuit 23.

The driving capability control system 1 according to the embodiment of the disclosure includes the receiver 20 and the driver 10. The driver 10 controls the driving capability of the drive signal S_{D} based on the control signal S_{C} supplied by the receiver 20.

By using the receiver 20 and the driving capability control system 1 according to the embodiment of the disclosure, the adjustment of the driving capability of the drive signal S_{D} output from the driver 10 may be automated.

With regard to the above embodiments, the following appendix are further disclosed.

### Appendix 1

A driving capability control device includes: an averaging circuit, averaging and outputting a drive signal including a pulse train supplied from a driver; a comparison circuit, outputting a comparison result of an output voltage level of the averaging circuit and a predetermined threshold voltage level; and a control circuit, outputting a control signal for controlling a driving capability of the drive signal based on an output of the comparison circuit.

### Appendix 2

In the driving capability control device according to Appendix 1, the control circuit outputs any one of a first control signal that includes an instruction to start adjusting the driving capability of the drive signal; a second control signal that includes an instruction to continue adjusting the driving capability of the drive signal; and a third control signal that includes an instruction to stop adjusting the driving capability of the drive signal, as the control signal.

### Appendix 3

In the driving capability control device according to Appendix 2, the control circuit outputs the second control signal when an output indicating that the output voltage level of the averaging circuit is lower than the threshold voltage level is output from the comparison circuit and outputs the third control signal when an output indicating that the output voltage level of the averaging circuit is higher than the threshold voltage level is output from the comparison circuit.

### Appendix 4

The driving capability control device according to Appendix 2 or Appendix 3 further includes a processing circuit that processes the drive signal supplied from the driver after the third control signal is output.

### Appendix 5

The driving capability control device according to any one of Appendix 1 to Appendix 4 further includes a switch for switching between supplying and non-supplying the drive signal to the averaging circuit.

### Appendix 6

In the driving capability control device according to any one of Appendix 1 to Appendix 5, the averaging circuit includes a low pass filter.

### Appendix 7

A driving capability control system includes the driving capability control device according to any one of Appendix 1 to Appendix 6 and the driver. The driver adjusts the driving capability of the drive signal based on the control signal.

### Appendix 8

In the driving capability control system according to Appendix 7, the control circuit outputs any one of a first control signal that includes an instruction to start adjusting the driving capability of the drive signal; a second control signal that includes an instruction to continue adjusting the driving capability of the drive signal; and a third control signal that includes an instruction to stop adjusting the driving capability of the drive signal, as the control signal. The driver supplies a drive signal for adjusting the driving capability including the pulse train with a constant duty and period to the driving capability control device until the third control signal is output after the first control signal is output from the control circuit.

### Appendix 9

In the driving capability control system according to Appendix 8, the driver stepwise increases the driving capability of the drive signal until the third control signal is output after the first control signal is output from the control circuit.

What is claimed is:

1. A driving capability control device, comprising:
an averaging circuit, averaging and outputting a drive signal comprising a pulse train supplied by a driver;
a comparison circuit, outputting a comparison result of an output voltage level of the averaging circuit and a predetermined threshold voltage level; and
a control circuit, outputting a control signal for controlling a driving capability of the drive signal based on an output of the comparison circuit.

2. The driving capability control device according to claim 1, wherein the control circuit outputs, as the control signal, any one of
a first control signal that comprises an instruction to start adjusting the driving capability of the drive signal;
a second control signal that comprises an instruction to continue adjusting the driving capability of the drive signal; and
a third control signal that comprises an instruction to stop adjusting the driving capability of the drive signal.

3. The driving capability control device according to claim 2, wherein the control circuit outputs the second control signal when an output indicating that the output voltage level of the averaging circuit is lower than the threshold voltage level is output from the comparison circuit and outputs the third control signal when an output indicating that the output voltage level of the averaging circuit is higher than the threshold voltage level is output from the comparison circuit.

4. The driving capability control device according to claim 2, further comprising a processing circuit that processes the drive signal supplied by the driver after the third control signal is output.

5. The driving capability control device according to claim 1, further comprising a switch for switching between supplying and non-supplying the drive signal to the averaging circuit.

6. The driving capability control device according to claim 1, wherein the averaging circuit comprises a low pass filter.

7. A driving capability control system, comprising:
the driving capability control device according to claim 1; and
the driver,
wherein the driver adjusts the driving capability of the drive signal based on the control signal.

8. The driving capability control system according to claim 7, wherein
the control circuit outputs, as the control signal, any one of
a first control signal that comprises an instruction to start adjusting the driving capability of the drive signal;
a second control signal that comprises an instruction to continue adjusting the driving capability of the drive signal; and
a third control signal that comprises an instruction to stop adjusting the driving capability of the drive signal, and
the driver supplies a drive signal for adjusting the driving capability comprising the pulse train with a constant duty and period to the driving capability control device until the third control signal is output after the first control signal is output from the control circuit.

9. The driving capability control system according to claim 8, wherein the driver stepwise increases the driving capability of the drive signal until the third control signal is output after the first control signal is output from the control circuit.
